(19) United States
(12) Patent Application Publication
(10) Pub. No.: US 2024/0380384 A1
(43) Pub. Date: Nov. 14, 2024

(54) Two-Dimensional Resonant Rod-Based Delay Line With High Bandwidth

(71) Applicant: Northeastern University, Boston, MA (US)

(72) Inventors: Cristian CASSELLA, Boston, MA (US); Onurcan KAYA, Boston, MA (US); Xuanyi ZHAO, Cambridge, MA (US)

(21) Appl. No.: 18/690,629

(22) PCT Filed: Sep. 28, 2022
(86) PCT No.: PCT/US2022/045076

§ 371 Date: Mar. 8, 2024

Related U.S. Application Data
(60) Provisional application No. 63/249,569, filed on Sep. 28, 2021.
(60) Provisional application No. 63/338,517, filed on May 5, 2022.

(51) Int. Cl. H03H 9/40; H03H 3/02

(52) U.S. Cl. CPC H03H 9/40; H03H 3/02

(57) ABSTRACT

An on-chip acoustic delay line (ADL) for operation in the radio frequency (RF) range uses a two-dimensional array of resonant rods and a piezoelectric layer having corrugated structure. The ADL has one or more programmable passband frequencies which are determined by the lithographically-defined artificial dispersive characteristics of acoustic metamaterials formed by forests of the locally resonant rods and selectable attached matching networks. The ADL devices offer exceptionally high fractional bandwidth and low insertion loss. The ADL can be used in self-interference cancellation networks to provide full duplex radio.

### CROSS-REFERENCE TO RELATED APPLICATIONS

This application claims priority to U.S. Provisional Appl. Nos. 63/249,569, filed 28 Sep. 2021, and 63/338,517, filed 5 May 2022. The entire content of both provisional applications is hereby incorporated by reference in their entireties.

### STATEMENT REGARDING FEDERALLY SPONSORED RESEARCH OR DEVELOPMENT

This invention was made with government support under Grant Number FA8650-21-1-7012 awarded by DARPA Defense Advanced Research Projects Agency. The government has certain rights in the invention.

### BACKGROUND

The recent development of CMOS-compatible circulators [1] has provided the fundamental means to build mobile communication systems for military and commercial applications relying on full-duplex radios (FDRs) to maximize the achievable spectral efficiency. Yet, due to the limited isolation that such circulators achieve, the use of FDRs in uncontrolled electromagnetic environments is only possible when electronically programmable self-interference (SI) cancellation networks, including a network of delay lines, are used in order to suppress the performance degradations due to leakage of the transmitted power into the receiver chain. In the last decades, several ADLs based on surface acoustic waves (SAW) [2] or Lamb wave (LW) [3] modes have been demonstrated. However, no ADL has shown the ability to achieve a large enough fractional bandwidth and a low enough insertion-loss (IL) to be used in the SI-cancellation networks of wideband FDRs, while preserving a CMOS-compatibility to favor their massive-scale production.

### SUMMARY

The present technology provides an on-chip acoustic delay line (ADL) for operation in the radio frequency (RF) range. The ADL uses an acoustic metamaterial containing a two-dimensional array of resonant rods and a piezoelectric layer having a corrugated structure. The ADL has one or more programmable passband frequencies, which are determined by the lithographically-defined dispersive characteristics of the acoustic metamaterials formed by forests of the locally resonant rods and selectable attached matching networks. The ADL devices of the present technology have exceptionally high fractional bandwidth and low insertion loss which are superior to previous ADL technology. The present ADL can be used in self-interference cancellation networks to provide full duplex radio, for example. Further, since the present ADL makes possible multiple acoustic passbands in a single microfabricated device, its operation can be electronically reprogrammed as needed by just varying the matching conditions. For example, a prototype ADL according to the present technology was shown to operate at four different frequencies within the Ultra-High-Frequency (UHF) range, exhibiting 3 dB fractional bandwidths up to 13.5%.

The present technology can be further summarized through the following listing of features.
1. An on-chip acoustic delay line device comprising:
a conductive substrate suspended over a cavity in the chip, wherein the conductive substrate is anchored to the chip outside the cavity by two anchor structures at opposite sides of the conductive substrate;
a piezoelectric layer comprising a sheet disposed on the conductive substrate and a parallel array of resonant rods disposed on the sheet, wherein the sheet comprises a piezoelectric material and the rods comprise a dielectric, metallic, or piezoelectric material;
wideband input and output terminals disposed on the piezoelectric sheet lateral to and at opposite ends of the parallel array, along a long axis of the resonant rods.
2. The device of feature 1, wherein the piezoelectric layer comprises a corrugated structure; wherein the corrugated structure is characterized by a repeating unit cell structure defined by a cross-section of the piezoelectric material sheet and the resonant rods;
wherein the cross-section comprises a plurality of the resonant rods, each pair of adjacent rods separated by a trench;
wherein a single unit cell extends from a midpoint of a first trench, through a rod adjacent to the first trench, to a midpoint of a second trench disposed at an opposite side of the rod;
wherein the unit cell dimensions include (i) a length extending from the midpoint of the first trench to the midpoint of the second trench, (ii) a first thickness of the sheet at the trenches; and (iii) a second thickness at the rod and including the thickness of the rod plus the thickness of the sheet; and
wherein the device comprises at least one acoustic passband, the passband determined by the unit cell dimensions and composition of the piezoelectric material.
3. The device of feature 2, wherein the first thickness is about 20% to about 30% of the second thickness.
4. The device of feature 2, wherein the corrugated structure is formed by etching away about 40% to about 90%, or about 70% to about 80%, of the piezoelectric material layer thickness to form the troughs.
5. The device of any of the preceding features, wherein the piezoelectric material is selected from the group consisting of AlN, scandium-doped AlN, BaTiO₃, LiNbO₃, LiTaO₃, ZnO, and lead zirconate titanate (Pb[ZrₓTi₍ₓ₋₁₎]O₃ wherein 0≤x≤1),
6. The device of feature 5, wherein the piezoelectric material comprises a scandium-doped aluminum nitride material.
7. The device of feature 6, wherein the piezoelectric material is aluminum nitride doped with scandium to a level of about 10%, about 20%, about 30%, about 40%, or about 50%, such as Al_{0.64}SC_{0.36}N.
8. The device of any of the preceding features, wherein an acoustic passband of the device has a center frequency in the radio frequency range and a 3 dB fractional bandwidth from about 5% to about 13.5%.
9. The device of any of the preceding features, wherein the device has an insertion loss of less than about 5 dB, less than about 3 dB, or less than about 2 dB.
10. The device of any of the preceding features, wherein the device has a delay time in the range of from about 30 ns to about 1 μs.
11. The device of any of the preceding features, wherein the conductive layer has a thickness of about 50 nm to about 500 nm.
12. The device of any of the preceding features, wherein the piezoelectric material layer has a thickness of about 100 nm to about 6 μm.
13. An acoustic delay line device comprising two or more acoustic delay line devices according to any of the preceding features, wherein the devices each have a separate chip cavity, and wherein the input and output terminals of the devices are connected in parallel.
14. The device of any of the preceding features, wherein the device has at least four separate passbands.
15. The device of feature 14, wherein the device has four passbands and the passbands have center frequencies of about 115 MHz, about 150 MHz, about 210 MHz, and about 300 MHz.
16. A frequency reprogrammable acoustic delay line system comprising:
a first acoustic delay line device, wherein the device is a device of any of the preceding features;
a first plurality of selectable matching networks electrically coupled to the wideband input terminal of the device; and
a second plurality of selectable matching networks electrically coupled to the wideband output terminal of the device.
17. The system of feature 16, wherein an operative frequency band of the system is controllable by a combined selection of one of the first plurality of matching networks and one of the second plurality of matching networks.
18. The system of feature 16 or feature 17, further comprising second and third acoustic delay line devices of any of features 1-15, wherein the second and third devices are electrically coupled to the wideband input and output terminals.
19. The system of feature 18, wherein the second and third devices are identical to the first device.
20. The system of any of features 16 to 19, wherein each of the first plurality of matching networks and the second plurality of matching networks includes at least two, at least three, or at least four matching networks.
21. The system of any of features 16-20, wherein the first plurality of matching networks is identical to the second plurality of matching networks.
22. Use of the device of any of features 1-15 or the system of any of features 16-21 in a tunable or non-tunable RF circuit for communication or sensing, in a self-interference cancellation electronic system, or in a quantum circuit for qubit readout.
23. A method of programming an acoustic delay line system in a plurality of frequency bands, the method comprising:
(a) providing the acoustic delay line system of any of features 16-21;
(b) selectively connecting one of a first plurality of matching networks to the wideband input terminal; and
(c) selectively connecting one of a second plurality of matching networks to the wideband output terminal.
24. The method of feature 23, further comprising alternatingly operating the acoustic delay line system at a plurality of different passbands.
25. The method of feature 24, wherein the system is operated at four passbands, and wherein the passbands have center frequencies of 115 MHz, 150 MHz, 210 MHz, and 300 MHz.
26. A method of fabricating an on-chip acoustic delay line device, the method comprising the steps of:
(a) depositing a conductive layer onto a chip substrate;
(b) depositing a piezoelectric layer onto the conductive layer;
(c) depositing a release pit mask onto the piezoelectric layer;
(d) etching voids into the piezoelectric and conductive layers;
(e) depositing a resonant rod array mask onto the piezoelectric layer;
(f) etching troughs into the piezoelectric layer, thereby forming a corrugated structure comprising an array of parallel resonant rods in the piezoelectric layer;
(g) depositing wideband input and output terminals at opposite ends of the array, along an axis transverse to a length direction of the resonant rods; and
(h) etching a release pit beneath the conductive layer, thereby forming the acoustic delay line device.
27. A method of fabricating an on-chip acoustic delay line device, the method comprising the steps of:
(a) depositing a conductive layer onto a chip substrate;
(b) depositing a piezoelectric layer onto the conductive layer;
(c) depositing a release pit mask onto the piezoelectric layer;
(d) etching voids into the piezoelectric and conductive layers;
(e) depositing a resonant rod array mask onto the piezoelectric layer;
(f) depositing resonant rods onto the piezoelectric layer;
(g) depositing wideband input and output terminals at opposite ends of the array, along an axis transverse to a length direction of the resonant rods; and
(h) etching a release pit beneath the conductive layer, thereby forming the acoustic delay line device.
28. The method of feature 26 or feature 27, wherein the method is CMOS compatible.

### BRIEF DESCRIPTION OF DRAWINGS

FIG. 1A shows a schematic illustration of an embodiment of an acoustic delay line (ADL) according to the present technology. The ADL includes two wideband input/output terminals and a corrugated structure between them. The corrugated structure creates an acoustic metamaterial and forms passbands depending on the geometry of the unit cell. FIG. 1B shows a corrugated structure of an ADL depicting an acoustic wave outside of its passband. FIG. 1C shows a corrugated structure of an ADL depicting an acoustic wave inside of its passband.

FIGS. 2A and 2B show the simulated performance of a 2D resonant rod array of an ADL. FIG. 2A indicates a fractional bandwidth of 11%, and FIG. 2B indicates an insertion loss of 0.86 dB. The inset of FIG. 2A represents propagation of an acoustic wave within the metamaterial.

FIGS. 3A-3D show scanning electron micrographs (SEM) of actual ADL devices. FIG. 3A shows a top view of a 3 array ADL, and FIG. 3B shows a close-up of a single element thereof. FIG. 3C shows a cross-sectional view of a unit cell during fabrication, with an oxide masking layer on top of a rod structure. FIG. 3D shows a labeled image of the single ADL element of FIG. 3B.

FIG. 4A shows the measured performance of an ADL having high fractional bandwidth of 7.5% and an insertion loss of 1.8 dB. FIG. 4B shows, for the same device, a group delay from about 30 ns to 50 ns over the bandwidth.

FIG. 5 shows a schematic representation of an embodiment of a fabrication process for an ADL device according to the present technology.

FIGS. 6A and 6B show cross-sectional schematic views of the corrugated structure of an ADL with unit cell features labeled. FIG. 6C shows real and imaginary parts of the analytically calculated K_{eff} for an ADL of the present technology. FIG. 6D shows the analytically calculated trend of T vs. frequency for an ADL of the present technology.

FIG. 7A shows a SEM of a system comprising a three-element fabricated ADL and four simulated switchable matching networks (I-IV) at each of the input and output terminals. Each of the matching networks has a different passband (corresponding to matching networks I-IV). Depending on the selected matching networks, the single device can be re-programmed to operate within different frequency bands. FIG. 7B shows both simulated (dashed lines) and measured (solid lines) responses of the ADL of FIG. 7A after matching to 50 Ω within different passbands. FIG. 7C shows close up views of data for the FEM-simulated (dashed lines) and measured (solid lines) insertion loss and group delay for each of the passbands shown in FIG. 7B.

### DETAILED DESCRIPTION

The present technology provides the first two-dimensional resonant rod (2DRR) based acoustic delay line (ADL) for operation in the radio frequency (RF) range. Contrary to any other ADLs reported to date, which are based on the piezoelectric excitation of surface acoustic waves (SAW) or Lamb waves (LW), the ADL described here relies on the lithographically defined artificial dispersive characteristics of acoustic metamaterials formed by forests of locally resonant rods. Further improved characteristics can be obtained by using piezoelectric materials having high piezoelectric coefficients, such as highly-doped aluminum scandium nitride (Al_{0.64}SC_{0.36}N) films. The 2DRR-based ADLs described here can operate over the entire ultra high frequency and super high frequency range, for example, at 133 MHz with a record-high fractional bandwidth of up to 15% (limited only by the bandwidth of the matching networks) and an insertion loss (IL) of less than 2 dB. These functional characteristics surpass the fundamental limits in bandwidth and IL of conventional SAW and LW counterparts

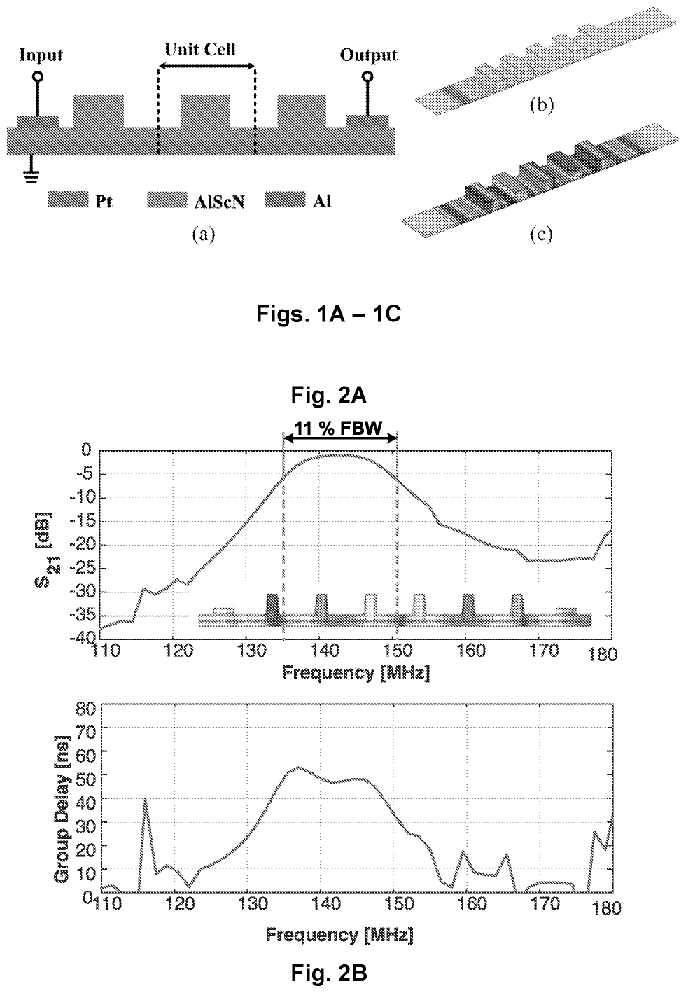

The present ADL devices possess wideband input/output terminals separated by a corrugated structure forming an acoustic metamaterial (FIG. 1A). The corrugated structure, which is formed by a forest of Al_{0.64}SC_{0.36}N rods, creates passbands (see FIGS. 1B, 1C) with bandwidths exceeding those achievable in conventional counterparts without requiring expensive materials, like LiNbO₃, which are not compatible with conventional CMOS processes. The unique performance features of the present 2DRR-based ADL were verified through Finite Element Methods (FEM, see FIGS. 2A, 2B).

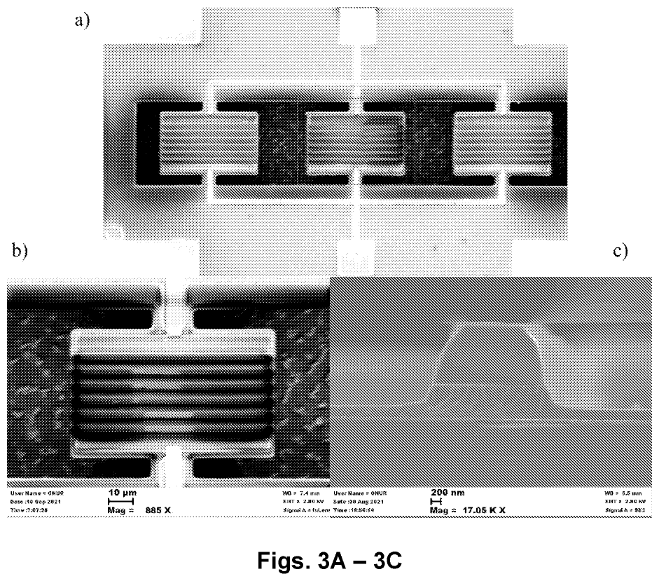

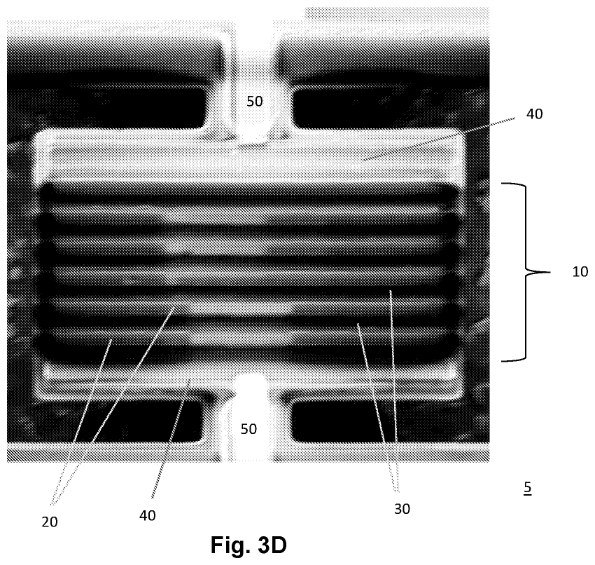

A scanning electron micrograph of the corrugated portion of an actual fabricated ADL device is shown in FIGS. 3A-3D. FIG. 3A shows a single device having three individual ADLs coupled in parallel to single input and output terminals. FIG. 3B shows a close up view of one of the individual devices. FIG. 3C shows a cross-section of a rod and adjacent troughs, with an oxide mask from the fabrication process still present on top of the rod.

FIG. 3D shows the individual array unit of FIG. 3B having its component parts labeled. ADL 5 includes 2D resonant rod array 10 disposed between two AL electrodes 40, (input/output terminals) which are connected via conductive paths through anchor structures 50 to conductive pads on the adjacent chip (not shown). The electrodes can be any conductive metal, such as Pt, Al, Mo, Cr, Ti, W, or Cu. The anchor structures are made of a beam of AlScN sandwiched between two platinum layers. Rod array 10 contains a group of rods 20 in parallel arrangement and separated by troughs 30. In this embodiment, the rods and troughs are formed by partially etching a single layer of Al_{0.64}SC_{0.36}N piezoelectric material.

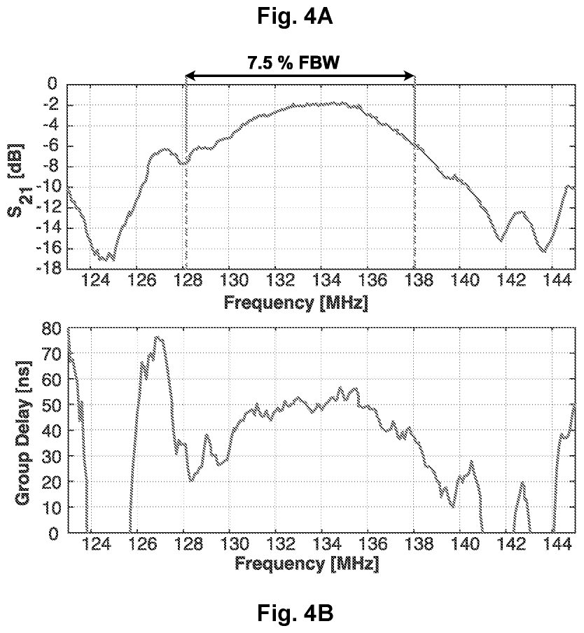

The performance of a fabricated ADL was characterized using a Network Analyzer, and the results are shown in FIGS. 4A and 4B. As evident, the constructed device exhibited record-high bandwidth and IL values of 7.5% and 1.8 dB when assuming conjugate matching as well as a group delay of nearly 50 nsecs. The delay is a function of the number of rods in the array, and can be increased by increasing the size of the resonant rod array.

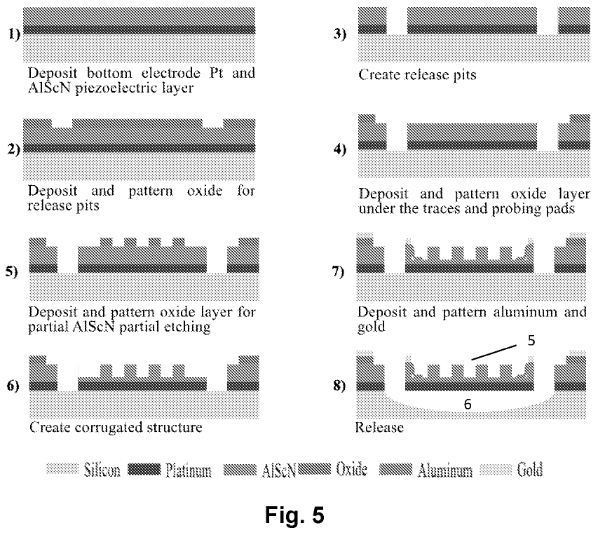

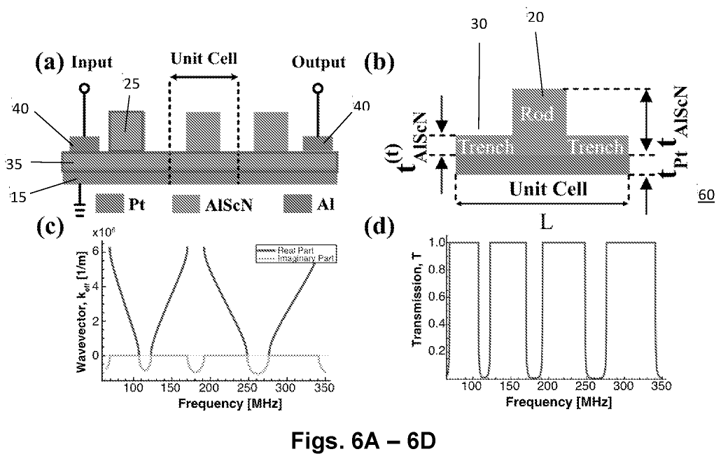

An exemplary process used to fabricate the present ADL devices is shown in FIG. 5, together with information about its material stack. The process began with the deposition of a bottom unpatterned 100 nm thick (t_{Pt}=100 nm) platinum layer (conductive substrate), followed by the sputtering of a 500 nm-thick Al_{0.64}SC_{0.36}N film onto the platinum layer. Secondly, the release holes for the structural release (i.e., to obtain a suspended ADL device attached to the chip via small anchor structures on opposite sides of the suspended device) were formed by etching the AlScN film with a SiO₂ hard mask. Following that, another silicon dioxide layer was deposited and patterned to be used under probing pads to reduce associated parasitic capacitance. Later, the corrugated structure was built by partial-etching (removing 80% of the thickness) of the AlScN film through the adoption of a third SiO₂ mask. Then, the top 140 nm thick Al electrode was patterned, forming the input and output terminals, followed by the deposition of the 300 nm thick gold terminals on top of the Al terminals as well as on the probing pads positioned on the adjacent silicon chip. Finally, the device was released through a XeF₂ Si-etch, leaving it attached to the chip through two small anchor structures at opposite ends of the device, Each anchor includes a beam of the piezoelectric material sandwiched between platinum layers, the lower of which is grounded.

In the exemplified device, the corrugated structure included 8 resonant rods containing scandium-doped aluminum nitride, connected by thin trenches of the same material. The propagation wavevectors depend on the dimensions and mechanical properties (determined by the selection of material) of the unit cell. FIGS. 6A and 6B depict the unit cell of the corrugated structure. In FIG. 6A can be seen conductive substrate layer 15, upon which is disposed sheet of piezoelectric material 35, with resonant rods 25 disposed on the sheet. In the exemplified device, the rods and sheet are made from a single layer of the same piezoelectric material; however, the rods can alternatively be deposited onto the sheet and made from a different material, including any dielectric, metallic, or piezoelectric material. The generation of stopband and passband does not require the rods to be piezoelectric. Any periodic distribution of rods can generate the desired perturbation of the modes that allows the formation of the bands. Therefore, non-piezoelectric rods will still perturb the entire mechanical behavior of the structure, perturbing the propagation features of acoustic waves travelling along the ADL. Input and output terminals 40 are deposited on the piezoelectric sheet.

The propagation wavevectors of both longitudinal and shear modes (K_{eff}) become imaginary in certain frequency bands, creating regions where the propagation of real energy is no longer possible. This also allows to manipulate the wave speed of both longitudinal and shear modes, providing the means to slow the acoustic propagation down when operating within any passbands. The analytically derived trends of the propagation vector (K_{eff}) and acoustic transmission coefficient (T) of to the exemplified device were estimated following the procedure discussed in [4] and are also shown in FIGS. 6C and 6D. As evident from FIG. 6D, the device exhibited wide acoustic passbands centered around four frequencies of interest. It should be noted that the electrical bandwidth of the ADL was lower than the bandwidth of T, being ultimately set by the Bode-Fano limit relative to the ADL's electrical matching.

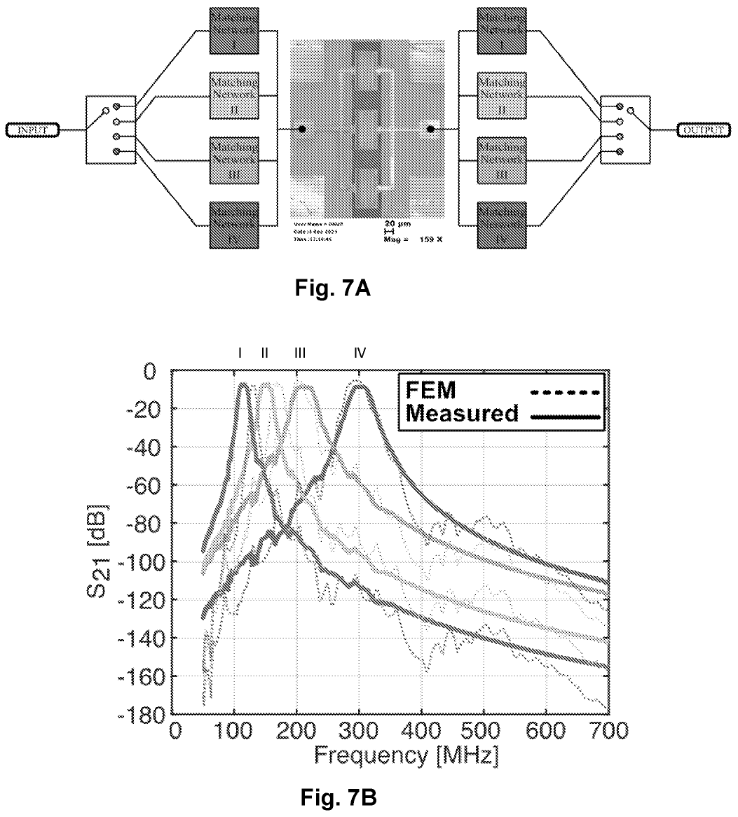

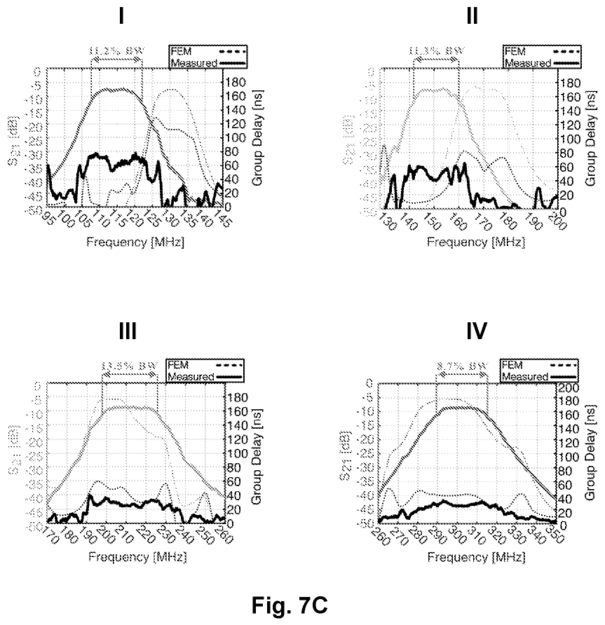

A system including the three array ADL described above and four alternate switchable matching networks was both simulated and fabricated. The matching networks for both simulation and measurement of responses were 50 Ω and included three inductors with quality factors (Qs) of lower than 100 and one capacitor. FIG. 7B shows the simulated and measured responses of the ADL system of FIG. 7A using the different passbands. FIG. 7C shows expanded views of the data for the FEM-simulated insertion loss and group delay for each of the four passbands shown in FIG. 7B. The ADL operated within four different passbands centered around 115 MHz, 150 MHz, 210 MHz, and 300 MHz. The 3 dB fractional bandwidth of each passband was 11.2%, 11.3%, 13.5%, and 8.7%, with a minimum recorded loss of ˜8 dB. The measured group delay varied between ˜70 ns and ˜30 ns. The large loss is believed due to excessive amounts of electrical loading, and can be improved by further optimizing the metal routing of the ADL.

The data described above demonstrate that the present technology provides frequency reprogrammable ADLs with up to 13.5% 3-dB fractional bandwidth and operable at four different frequencies (such as 115 MHz, 150 MHz, 210 MHz, and 300 MHz), each one corresponding to the center frequency of an acoustic passband generated by the metamaterial structure. This frequency re-programmability, which is achievable with selection of suitable matching conditions and is enabled by the unique dispersion features of the metamaterial structure, which is not present in any ADLs based on LW or SAW. ADLs based on LW or SAW cannot achieve frequency re-programmability.

In addition to the frequency programmability feature shown above, the present technology has several novel and useful features and advantages. The ADL devices of the present technology use wideband input and output transducers to radiate and receive an acoustic wave. The transducers separate a corrugated piezoelectric structure forming an acoustic metamaterial. This structure generates passbands for the propagation of shear-vertical (SV) modes characterized by much wider bandwidths than achievable through any existing counterparts. The ADL and systems including it can be formed by arrays of identical devices so as to achieve an easier and more performant electrical matching when connected to any electrical system. The center frequency of the ADL can be set lithographically by simply varying the geometry of the unit-cell forming the acoustic (piezoelectric) metamaterial, and based on the known properties of the material.

The presently disclosed ADL devices and systems surpass the previous material-limited values of bandwidth and IL achieved by conventional ADLs. The ability to engineer the acoustic dispersion of the ADL makes the ADL ideal to form the delay lines needed by any self-interference cancellation feature in full-duplex RF systems. The ADL does not need any patterning of the bottom metal plate underneath the required piezoelectric layer. This is an important advantage over previous ADLs, which require patterning of the bottom metal plate, even though this significantly degrades the quality of the piezoelectric film. The present ADL achieves a group velocity that is exceptionally slow (nearly 1000 m/s). The ability to achieve such a slow speed is particularly relevant in applied physics, where classical or quantum wave-matter interaction is of great interest. When a piezoelectric material like AlN or AlScN is used, the present ADL can be manufactured together with the rest of the complementary electronics on a chip, ensuring the highest possible performance and reduced manufacturing costs compared to use of other materials. The ultra-low form factor of the present ADL makes it possible to achieve exceptionally miniaturized RF systems, with benefits in terms of cost per fabricated unit within a mass-scale production framework.

The present ADL can be used to fabricate any type of passive RF component, similarly to electromagnetic ADLs, but with the ability to reduce the form factor by 100000-fold or more. The ADL can be used as the required delay element in self-interference cancellation networks, such as those needed to practically use any full-duplex radio in uncontrolled electromagnetic environments. The ADL can be used to make filter components with exceptional bandwidth that surpass by a great extent what was possible to attain previously using on-chip counterparts. The present technology can be used to develop ADLs for on-chip RF components in wideband radios, such as those needed for 4G-to-5G communication. It also can be used to make RF components for space applications, as well as to make exceptionally slow-wave guiding structures for future quantum devices and systems.

As used herein, “consisting essentially of” allows the inclusion of materials or steps that do not materially affect the basic and novel characteristics of the claim. Any recitation herein of the term “comprising”, particularly in a description of components of a composition or in a description of elements of a device, can be exchanged with “consisting essentially of” or “consisting of”.

While the present invention has been described in conjunction with certain preferred embodiments, one of ordinary skill, after reading the foregoing specification, will be able to effect various changes, substitutions of equivalents, and other alterations to the compositions and methods set forth herein.

### References

[1] Y. Yu et al., “Highly-Linear Magnet-Free Microelectromechanical Circulators,” Journal of Microelectromechanical Systems, vol. 28, no. 6, pp. 933-940, 2019, doi: 10.1109/jmems.2019.2947903.
[2] R. Lu, Y. Yang, A. E. Hassanien, and S. Gong, “Gigahertz Low-Loss and High Power Handling Acoustic Delay Lines Using Thin-Film Lithium-Niobate-on-Sapphire,” IEEE Transactions on Microwave Theory and Techniques, vol. 69, no. 7, pp. 3246-3254, 2021, doi: 10.1109/TMTT.2021.3074918.
[3] R. Lu, S. Link, S. Zhang, M. Breen, and S. Gong, “Aluminum Nitride Lamb Wave Delay Lines With Sub-6 dB Insertion Loss,” Journal of Microelectromechanical Systems, vol. 28, no. 4, pp. 569-571, 2019, doi: 10.1109/JMEMS.2019.2919031.
[4] X. Zhao, L. Colombo, and C. Cassella, “Aluminum nitride two-dimensional-resonant-rods,” Applied Physics Letters, vol. 116, no. 14, 2020, doi: 10.1063/5.0005203.

1. An on-chip acoustic delay line device comprising:
a conductive substrate suspended over a cavity in the chip, wherein the conductive substrate is anchored to the chip outside the cavity by two anchor structures at opposite sides of the conductive substrate;
a piezoelectric layer comprising a sheet disposed on the conductive substrate and a parallel array of resonant rods disposed on the sheet, wherein the sheet comprises a piezoelectric material and the rods comprise a dielectric, metallic, or piezoelectric material;
wideband input and output terminals disposed on the piezoelectric sheet lateral to and at opposite ends of the parallel array, along a long axis of the resonant rods.

2. The device of claim 1, wherein the piezoelectric layer comprises a corrugated structure; wherein the corrugated structure is characterized by a repeating unit cell structure defined by a cross-section of the piezoelectric material sheet and the resonant rods;
wherein the cross-section comprises a plurality of the resonant rods, each pair of adjacent rods separated by a trench;
wherein a single unit cell extends from a midpoint of a first trench, through a rod adjacent to the first trench, to a midpoint of a second trench disposed at an opposite side of the rod;
wherein the unit cell dimensions include (i) a length extending from the midpoint of the first trench to the midpoint of the second trench, (ii) a first thickness of the sheet at the trenches; and (iii) a second thickness at the rod and including the thickness of the rod plus the thickness of the sheet; and
wherein the device comprises at least one acoustic passband, the passband determined by the unit cell dimensions and composition of the piezoelectric material.

3. The device of claim 2, wherein the first thickness is about 20% to about 30% of the second thickness.

4. The device of claim 2, wherein the corrugated structure is formed by etching away about 40% to about 90%, or about 70% to about 80%, of the piezoelectric material layer thickness to form the troughs.

5. The device of claim 1, wherein the piezoelectric material is selected from the group consisting of AlN, scandium-doped AlN, BaTiO₃, LiNbO₃, LiTaO₃, ZnO, and lead zirconate titanate (Pb[ZrₓTi₍ₓ₋₁₎]O₃ wherein 0≤x≤1),

6. The device of claim 5, wherein the piezoelectric material comprises a scandium-doped aluminum nitride material.

7. The device of claim 6, wherein the piezoelectric material is Al_{0.64}Sc_{0.36}N.

8. The device of claim 1, wherein an acoustic passband of the device has a center frequency in the radio frequency range and a 3 dB fractional bandwidth from about 5% to about 13.5%.

9. The device of claim 1, wherein the device has an insertion loss of less than about 5 dB, less than about 3 dB, or less than about 2 dB.

10. The device of claim 1, wherein the device has a delay time in the range of from about 30 ns to about 1 μs.

11. The device of claim 1, wherein the conductive layer has a thickness of about 50 nm to about 500 nm.

12. The device of claim 1, wherein the piezoelectric material layer has a thickness of about 100 nm to about 6 μm.

13. An acoustic delay line device comprising two or more acoustic delay line devices according to claim 1, wherein the input and output terminals of the devices are connected in parallel.

14. The device of claim 1, wherein the device has at least four separate passbands.

15. The device of claim 14, wherein the device has four passbands and the passbands have center frequencies of about 115 MHz, about 150 MHz, about 210 MHz, and about 300 MHz.

16. A frequency reprogrammable acoustic delay line system comprising:
a first acoustic delay line device, wherein the device is a device of claim 1;
a first plurality of selectable matching networks electrically coupled to the wideband input terminal of the device; and
a second plurality of selectable matching networks electrically coupled to the wideband output terminal of the device.

17. The system of claim 16, wherein an operative frequency band of the system is controllable by a combined selection of one of the first plurality of matching networks and one of the second plurality of matching networks.

18. The system of claim 16, further comprising second and third said acoustic delay line devices, wherein the second and third devices are electrically coupled to the wideband input and output terminals.

19. The system of claim 18, wherein the second and third devices are identical to the first device.

20. The system of claim 16, wherein each of the first plurality of matching networks and the second plurality of matching networks includes two or more matching networks, such as four matching networks.

21. The system of claim 16, wherein the first plurality of matching networks is identical to the second plurality of matching networks.

22. Use of the device of claim 1 in a tunable or non-tunable RF circuit for communication or sensing, in a self-interference cancellation electronic system, or in a quantum circuit for qubit readout.

23. A method of programming an acoustic delay line system in a plurality of frequency bands, the method comprising:
(a) providing the acoustic delay line system of claim 16;
(b) selectively connecting one of a first plurality of matching networks to the wideband input terminal; and
(c) selectively connecting one of a second plurality of matching networks to the wideband output terminal.

24. The method of claim 23, further comprising alternatingly operating the acoustic delay line system at a plurality of different passbands.

25. The method of claim 24, wherein the system is operated at four passbands, and wherein the passbands have center frequencies of 115 MHz, 150 MHz, 210 MHz, and 300 MHz.

26. A method of fabricating an on-chip acoustic delay line device, the method comprising the steps of:
(a) depositing a conductive layer onto a chip substrate;
(b) depositing a piezoelectric layer onto the conductive layer;
(c) depositing a release pit mask onto the piezoelectric layer;
(d) etching voids into the piezoelectric and conductive layers;
(e) depositing a resonant rod array mask onto the piezoelectric layer;
(f) etching troughs into the piezoelectric layer, thereby forming a corrugated structure comprising an array of parallel resonant rods in the piezoelectric layer;
(g) depositing wideband input and output terminals at opposite ends of the array, along an axis transverse to a length direction of the resonant rods; and
(h) etching a release pit beneath the conductive layer, thereby forming the acoustic delay line device.

27. A method of fabricating an on-chip acoustic delay line device, the method comprising the steps of:
(a) depositing a conductive layer onto a chip substrate;
(b) depositing a piezoelectric layer onto the conductive layer;
(c) depositing a release pit mask onto the piezoelectric layer;
(d) etching voids into the piezoelectric and conductive layers;
(e) depositing a resonant rod array mask onto the piezoelectric layer;
(f) depositing resonant rods onto the piezoelectric layer;
(g) depositing wideband input and output terminals at opposite ends of the array, along an axis transverse to a length direction of the resonant rods; and
(h) etching a release pit beneath the conductive layer, thereby forming the acoustic delay line device.

28. The method of claim 26, wherein the method is CMOS compatible.

28. The method of claim 27, wherein the method is CMOS compatible
